(19) United States
(12) Patent Application Publication
(10) Pub. No.: US 2001/0050566 A1
(43) Pub. Date: Dec. 13, 2001

(54) Printed circuit board for use in the testing of electrical components and method for producing it

(76) Inventor: Hans-Jurgen Hacke, Munchen (DE)

Correspondence Address: LERNER AND GREENBERG, P.A., Post Office Box 2480, Hollywood, FL, 33022-2480, US

(21) Appl. No.: 09/789,972

(22) Filed: Feb. 20, 2001

Related U.S. Application Data
(63) Continuation of application No. PCT/DE99/02565, filed on Aug. 16, 1999.

(30) Foreign Application Priority Data
Aug. 18, 1998 (DE) 198 37 392.9

(51) Int. Cl. G01R 31/02

(52) U.S. Cl. 324/754

(57) ABSTRACT

A printed circuit board for use in testing electrical components having distributed two-dimensional connection contacts. The printed circuit board has an electrically insulating insulation layer provided with through-holes. In the region of a respective through-hole, an electrically conductive contact pad is provided on a side surface of the insulation layer. Proceeding from a respective contact pad, a respective conductor track extends to an edge region of the insulation layer.

### CROSS-REFERENCE TO RELATED APPLICATION

This application is a continuation of copending International Application No. PCT/DE99/02565, filed Aug. 16, 1999, which designated the United States.

### BACKGROUND OF THE INVENTION

1. Field of the Invention

The invention relates to a printed circuit board for use in the testing of electrical components having distributed two-dimensional connection contacts, and also to a method for producing such a printed circuit board.

The testing of electrical components can be explained with reference to the testing of chip-size or chip-scale packages. In the case of these designs of integrated circuits, a check is made prior to packaging to determine whether the integrated circuits operate in a manner that is dynamically electrically proper. In a first step, the integrated circuits are tested statically directly after fabrication on a semiconductor wafer. After the processes of sawing from the wafer and contact-connection into a chip-size package, it is necessary to test these integrated circuits again, because they have been subjected to further process steps in which additional fault sources can occur. This is carried out since the packaging of fault-free components is a prerequisite in the case of the connecting methods currently used in which the contacts which are no longer visible and monitorable, and in particular in the case of multichip modules, in order to achieve an acceptable overall yield.

For this purpose, U.S. Pat. No. 5,510,721 discloses a test device for testing an integrated circuit. The test device uses conductive strips extending over trenches. The strips are aligned with connection contacts on the integrated circuit. When these bond contacts or connection contacts of the integrated circuit are brought into contact with the strips, the strips exert a counterforce in the opposite direction in order to ensure a good electrical contact during the testing of the integrated circuit.

Electrical testing using known test devices proves to be problematic precisely in the case of electrical components having a multiplicity of contacts. Such components often have ball-like connection bumps with which contact can be made only with difficulty using test needles of test adapters or the known metallic test strips. Moreover, when testing using test needles, it can happen that the test needles damage the integrated circuit being tested.

U.S. Pat. No. 5,065,506 discloses a method for producing a printed circuit board which provides an electrical line on one side of a substrate and carries out selective irradiation of the other side of the substrate with a laser beam, thereby sublimating a section of the substrate. An opening is made in the process and a line traverses the opening. This line is subsequently bonded on contact areas of an electrical component.

### SUMMARY OF THE INVENTION

It is accordingly an object of the invention to provide a printed circuit board and a method for testing electrical components on the printed circuit board which overcomes the above-mentioned disadvantageous of the prior art apparatus and methods of this general type, and which in particular simplifies the testing of the electrical components.

With the foregoing and other objects in view there is provided, in accordance with the invention, a printed circuit board for use in testing an electrical component having distributed two dimensional electrical contacts. The printed circuit board includes an electrically insulating insulation layer provided with through openings. In a region of a respective through opening, an electrically conductive contact pad is provided on a surface of the insulation layer, with the result that a contact point of the electrical component comes into contact with a contact pad of the printed circuit board. Proceeding from a respective contact pad, a respective conductor track extends to an edge region of the insulation layer. Elastic spring elements are provided at least in the region of the through openings below the contact pads and are arranged in such a way that the contact pads each make contact with a spring element.

The invention is based on the fundamental concept of providing a flexible test structure which provides an elastic press-on connection with contact points of electrical components. The electrical component can be pressed by its contact points onto the printed circuit board in such a way that a respective contact point of the electrical component comes into contact with a contact pad of the printed circuit board. The contact pad, which is situated in particular above the through opening, can yield into the through opening or out of the through opening and thus compensate for tolerances in the formation of contact points of the electrical component. Furthermore, damage to contact points of the electrical component is avoided.

In accordance with an added feature of the invention, the elastic spring elements may be arranged in such a way that the contact pads each make contact with a spring element through the through openings. With these configurations, it is possible for the compliance of the contact pads to be accurately set independently of their position with regard to the through openings.

In accordance with an additional feature of the invention, the contact pads lie between the insulation layer and the elastic spring element. A contact element of an electrical component can then be connected to the contact pad through the through openings. The spring element compensats for tolerance differences between the contact pad and connection bump. As an alternative to this, the elastic spring element may also be arranged within the through opening, in which case the contact pad can be forced into the through opening by a contact point of an electrical component against the resistance of the spring element.

In accordance with another feature of the invention, the spring elements may be designed as contiguous regions of an elastic mating layer, which may have silicone rubber. This allows the printed circuit board to be produced in a particularly simple manner.

In accordance with a further feature of the invention, the contact pads may also be arranged at least partly in a self-supporting manner in the through openings, as a result of which simplified and reliable use of the printed circuit board according to the invention can be achieved.

With the foregoing and other objects in view there is provided, in accordance with the invention, a method for producing a printed circuit board for testing an electrical component having distributed two dimensional electrical contacts, the method includes steps of: providing an electrically insulating insulation layer having an edge region and a side coated with a conductive metal layer; producing through-holes at locations in the insulation layer that are intended to contact the electrical contacts of the electrical component, and producing contact pads adjacent the through-holes so that contact points can be formed between the electrical contacts of the electrical component and the contact pads; producing conductor tracks in the conductive metal layer which each extend from a location adjacent a respective one of the through-holes to the edge region of the insulation layer; providing elastic spring elements at least in locations that are adjacent the through-holes and that are also below the contact pads; and configuring the elastic spring elements so that each one of the contact pads contacts a respective one of the elastic spring elements.

In accordance with an added mode of the invention, it is possible to provide the electrically insulating insulation layer coated with a conductive metal layer. Such support materials can be obtained cost-effectively, so that the production of the printed circuit board according to the invention can be carried out economically.

In accordance with an additional mode of the invention, the through openings are made in the insulation layer preferably by laser ablation using a mask, while the production of conductor tracks in the metal layer can be carried out for example by means of a photolithographic and etching method.

The use of laser ablation allows the use of already coated support materials in the inventive method, since only the insulation layer can be removed by the laser ablation, while the copper coating remains in the region of the through opening.

The through opening may also be produced by chemical and/or physical etching or by stamping.

If the step of producing contact pads is provided, to be precise in each case as a section of a conductor track in a region of a through opening, then it is possible to produce a printed circuit board which functions particularly reliably in use. Such contact pads may be permanently protected against corrosion, for example by depositing a metal, in particular gold.

In the inventive methods and in the printed circuit board, the production of the flexible test structure is based on the use of process steps which are also employed during spider production for TAB mounting (Tape Automated Bonding). In this case, particularly fine conductor structures can be produced, in particular also in a self-supporting manner above openings in the support material.

In accordance with another mode of the invention, this method is used to produce self-supporting, gold-plated contact pads for connections of an electrical component which is to be tested. The electrical component is then pressed onto these contact pads, so that a spring element fitted behind and made of silicone rubber, for example, is used both to compensate for tolerances and to produce a good electrical test contact. From the contact pads, conductor tracks lead to connections in a coarser grid pattern, which can be connected to test bases and other elements in a customary way.

The openings in the support sheet into which the contact pads project can be produced in various ways. Thus, chemical or plasma etching can be employed in the same way as methods of laser removal. The possibility of using stamping depends on the grid-pattern fineness and the hole diameter of the through openings.

Unlike the usual case, a certain edge bevel of the hole cross-section of the through openings is desirable in the present case. This is because if, in the case of testing, the component is pressed onto the test structure from the opening side, then the hole edges bring about a centering effect, which correspondingly increases the required positioning accuracy.

However, in a variant, the component can also be pressed on from the other side. In this case, the resilient material must fill the openings, and this can be achieved by placing the sheet for example onto a liquid bed of silicon rubber with subsequent curing.

Other features which are considered as characteristic for the invention are set forth in the appended claims.

Although the invention is illustrated and described herein as embodied in a printed circuit board for use in the testing of electrical components and method for producing it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows a plan view of a printed circuit board;

FIG. 2 shows a cross-section through another printed circuit board in a region of a through opening;

FIG. 3 shows a cross-section through another printed circuit board in a region of another through opening;

FIG. 4 shows a cross-section through an electrical component to be tested and also through the printed circuit board shown in FIG. 3, in a region of two through openings;

FIG. 5 shows a cross-section through another electrical component and also through the printed circuit board shown in FIG. 2, in the region of further through openings; and

FIG. 6 shows a plan view of another printed circuit board.

### DESCRIPTION OF THE PREFERRED EMBODIMENTS

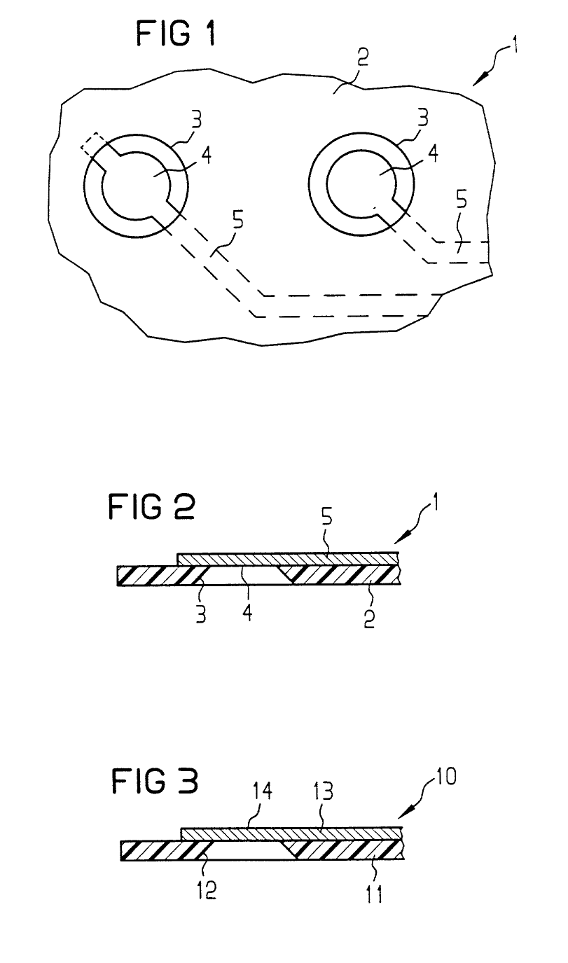

Referring now to the figures of the drawing in detail and first, particularly, to FIG. 1 thereof, there is shown a plan view of a printed circuit board 1. The printed circuit board 1 is subdivided into an electrically insulating insulation layer 2 having through openings 3.

Electrically conductive contact pads 4, which are gold-plated, are arranged in a freely suspended manner within the through openings 3. Furthermore, conductor tracks 5 are provided on the underside of the insulation layer 2, which conductor tracks extend across the through openings and are connected to the contact pads 4.

In order to produce the printed circuit board 1, the through openings 3 are produced in a copper-coated support material having a thickness of e.g. 50 μm, to be precise by laser ablation using a mask which is not shown in this view.

Afterward, the copper coating provided on the rear side of the insulation layer 2 in FIG. 1 is coated with photoresist and the structure of the conductor tracks 5 is exposed with register accuracy with respect to the opening pattern. After the photoresist (not shown in this view) has been developed, the copper coating is etched and stripped. Finally, the contact pads 4, in particular, are coated with gold.

FIG. 2 shows a region of the printed circuit board 1 around a through opening 3 in cross section. As can be seen particularly well in this view, the contact pad 4, proceeding from the conductor track 5, extends into the through opening 3. An edge bevel of the through opening 3 toward the contact pad 4 is desirable.

FIG. 3 shows a partial region of another printed circuit board 10 in cross section.

The printed circuit board 10 is subdivided into an insulation layer 11, in which a through opening 12 is provided. A conductor track 13 is deposited above the insulation layer 11, a circular contact pad 14 coated with gold has been produced in the conductor track.

The printed circuit board 10 is produced by a TAB method (=Tape Automated Bonding method).

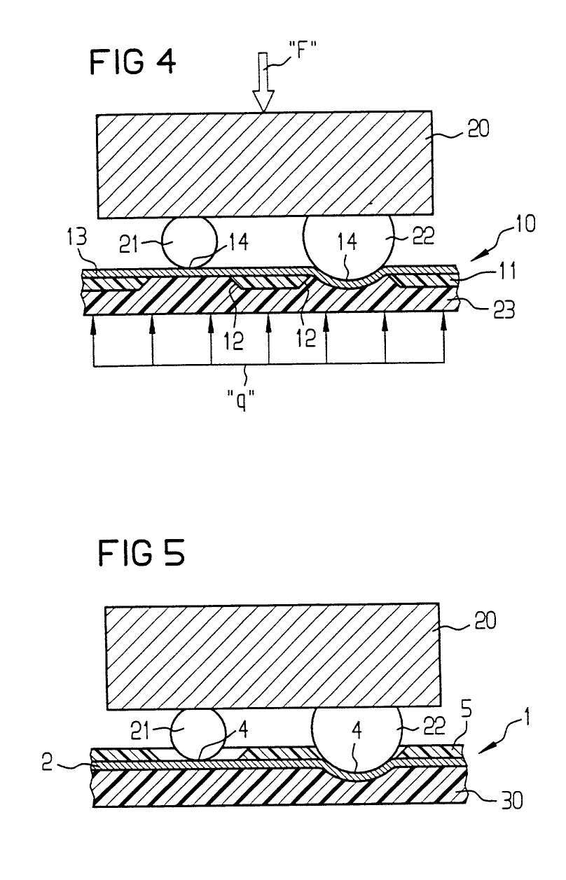

FIG. 4 illustrates the printed circuit board 10 shown in FIG. 3 when used with an electrical component 20 to be tested, which, on its underside, has a first contact bump 21 having an essentially circular cross section and also a second contact bump 22 having an essentially circular cross section. Within the tolerance range, the diameter of the second contact bump 22 is significantly greater than the diameter of the first contact bump 21.

As can be seen particularly clearly in FIG. 4, the through openings 12 are arranged in the insulation layer 11 in such a way that they lie exactly under the first contact bump 21 and under the second contact bump 22. In this case, the first contact bump 21 just touches the contact pad 14 of the through opening shown on the left-hand side in FIG. 4, while the second contact bump 22 presses downward the contact pad 14 of the through opening shown on the right-hand side in FIG. 4.

In order to increase the flexural resistance of the contact pads 14, a spring layer 23 made of silicone rubber is provided below the insulation layer 11. The spring layer bears on a fixed support not shown in this view. A press-on force “F” on the electrical component 20 is counteracted by the spring layer 23 with an area load “q”.

By virtue of the design of the contact pads 14 in conjunction with the flexible conductor track 13, size tolerances between first contact bump 21 and second contact bump 22 are compensated for, as can be seen particularly well in FIG. 4.

FIG. 5 illustrates the printed circuit board 1 shown in FIG. 2 in conjunction with the electrical component 20 from FIG. 4. A spring layer 30 is provided below the insulation layer 2 and the conductor tracks 5. The spring layer counteracts deformation of the contact pads 4 downward under the action of the first contact bump 21 and of the second contact bump 22. As is seen particularly well in this view, this configuration ensures tolerance compensation on account of the different sizes of first contact bump 21 and second contact bump 22.

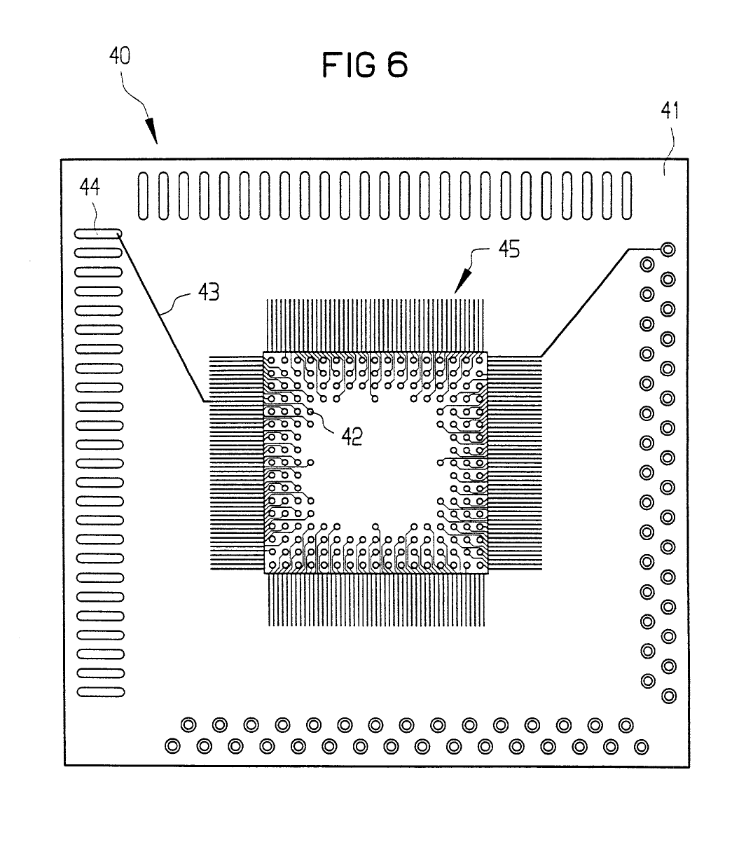

FIG. 6 shows another printed circuit board 40 according to the invention in plan view. The printed circuit board 40 has an insulation layer 41, on which a copper coating is applied. A series of conductor tracks have been formed in the copper coating, which conductor tracks are designed for the purpose of test contact-connection of a component. In this case, each contact bump present on the underside of an electrical component (not shown in this view) is assigned a through opening with contact pad, as is shown in more detail in FIGS. 3 and 4. A contact pad 42 is singled out here by way of example, this contact pad is connected via a conductor track 43 to a coarse connection 44 at the edge of the insulation layer 41. Likewise, all of the other contact pads in a contact region 45 of the printed circuit board 40 are also connected to coarse connections on the periphery of the printed circuit board 40.

In order to check an electrical component whose contact bumps are arranged in the same way as the contact pads in the component region of the contact region 45, the component is pressed onto the contact region 45. All of the contact bumps of the electrical component can thereupon be scanned via the coarse connections on the periphery of the printed circuit board 40.

I claim:

1. A printed circuit board for use in testing an electrical component having distributed two dimensional electrical contacts, the printed circuit board, comprising:
an electrically insulating insulation layer having a surface and an edge region and formed with a plurality of through-holes therein;
a plurality of electrically conductive contact pads disposed adjacent said plurality of said through-holes and disposed at said surface of said insulation layer, said plurality of said electrically conductive contact pads disposed for contacting the electrical contacts of the electrical component;
a plurality of conductor tracks extending from said plurality of said electrically conductive contact pads to said edge region of said insulation layer; and
a plurality of elastic spring elements, each one of said plurality of said elastic spring elements disposed adjacent a respective one of said plurality of said through-holes and disposed below a respective one of said plurality of said contact pads for contacting said respective one of said plurality of said contact pads.

2. The printed circuit board according to claim 1, wherein each one of said plurality of said elastic spring elements is disposed to contact said respective one of said plurality of said contact pads through a respective one of said through-holes.

3. The printed circuit board according to claim 1, comprising an elastic mating layer having contiguous regions forming said plurality of said elastic spring elements.

4. The printed circuit board according to claim 3, wherein said mating layer includes silicone rubber.

5. The printed circuit board according to claim 1, wherein said plurality of said contact pads are disposed at least in said through-holes in a self-supporting manner.

6. A method for producing a printed circuit board for testing an electrical component having distributed two dimensional electrical contacts, the method which comprises:
providing an electrically insulating insulation layer having an edge region and a side coated with a conductive metal layer;
producing through-holes at locations in the insulation layer that are intended to contact the electrical contacts of the electrical component, and producing contact pads adjacent the through-holes so that contact points can be formed between the electrical contacts of the electrical component and the contact pads;
producing conductor tracks in the conductive metal layer which each extend from a location adjacent a respective one of the through-holes to the edge region of the insulation layer;
providing elastic spring elements at least in locations that are adjacent the through-holes and that are also below the contact pads; and
configuring the elastic spring elements so that each one of the contact pads contacts a respective one of the elastic spring elements.

7. The method according to claim 6, wherein the electrically insulating insulation layer is provided as a support material and the conductive metal layer is made from copper.

8. The method according to claim 6, which comprises performing the step of producing the through-holes by laser ablation using a mask.

9. The method according to claim 6, wherein the conductor tracks are produced in the conductive metal layer by photolithography and etching.

10. The method according to claim 6, which comprises providing each one of the contact pads as a section of a respective one of the conductor tracks at a region adjacent a through-hole.

11. The method according to claim 10, which comprises depositing gold on the contact pads, after performing the step of producing the contact pads.
